(19) United States
(12) Patent Application Publication
(10) Pub. No.: US 2009/0009968 A1
(43) Pub. Date: Jan. 8, 2009

(54) Cooling device and electronic apparatus

(76) Inventor: Takeshi Hongo, Sagamihara-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/710,821

(22) Filed: Feb. 26, 2007

(30) Foreign Application Priority Data
Feb. 28, 2006 (JP) 2006-052217

(51) Int. Cl. H05K 7/20; F28D 15/00

(52) U.S. Cl. 361/699; 165/104.33

(57) ABSTRACT

According to one embodiment, a cooling device has a base substance formed in a plate form and having in its inside a channel through which a refrigerant circulates, and a flow mechanism that generates a stream of the refrigerant along the channel. The base substance has a first heat receiving part, a second heat receiving part and a heat radiating part. The first heat receiving part has in its inside a first heat receiving section thermally connected to the first heat generator. The second heat receiving part has in its inside a second heat receiving section thermally connected to the second heat generator. The heat radiating part has in its inside a heat radiating section located downstream of the first heat receiving section and the second heat receiving section.

### CROSS-REFERENCE TO RELATED APPLICATIONS

This application is based upon and claims the benefit of priority from the Japanese Patent Application No. 2006-052217, filed Feb. 28, 2006, the entire contents of which are incorporated herein by reference.

### BACKGROUND

1. Field

One embodiment of the invention relates to a cooling device and an electronic apparatus which is provided with this cooling device, for example, which removes heat of a plurality of heat generators by one cycling pathway through which a refrigerant flows.

2. Description of the Related Art

An electronic apparatus has a large number of electronic components on a circuit board incorporated in its housing. Among the electronic components, those which generate heat during operation have a cooling device installed to positively remove heat. In the electronic apparatus shown in FIGS. 1 and 2 of U.S. Pat. No. 5,646,824, multiple circuit boards with semiconductor elements mounted thereon are arranged in a overlapped state inside the housing. Individual semiconductor elements are thermally connected to heat-receiving-side headers inside which a channel to flow refrigerant is formed.

The heat-radiation side header which composes a heat exchanging radiator is provided with multiple heat radiating pipes through which a refrigerant flows inside and fins mounted to the outer circumferential surface of these heat radiating pipes. The heat radiating pipes are coupled with the heat-receiving-side headers plurally provided in series by being connected to each heat-receiving side header by flexible tubes. In addition, the heat exchanging radiator has a liquid transfer mechanism which transfers a refrigerant between the heat-receiving side header and the heat-radiating side header. One bellows which serve as liquid transfer mechanisms is connected to both ends of the channel configured in series respectively. Both bellows are repeatedly expanded and contracted by a drive motor coupled with one bellows. As a result, a refrigerant reciprocates in the channel configured in series by the heat-receiving-side header, flexible tubes, and radiation pipes.

Furthermore, in FIGS. 4, 5, and 9 to 11 of U.S. Pat. No. 5,646,824, an embodiment in which a cooling device is described inside a notebook portable computer body is stipulated. The portable computer has one semiconductor element in a circuit board built into the housing. A heat-receiving-side header having the same shape as that of the heat-receiving-side header shown in FIG. 2 is mounted on the semiconductor element. In addition, it is disclosed that a refrigerant is circulated by a small pump.

As the wiring density of integrated circuits of central processing units (CPUs), etc. increases, the heat quantity which CPU generates increases. In addition, as a result, the heat quantity in electronic components in which processing is conducted in linkage with CPU is increasing, too. Consequently, these peripheral electronic components must be positively cooled in the same manner as is the case of CPU.

Configuring a channel in such a manner that a refrigerant successively passes through heat generators scattered on the same circuit board degrades the cooling efficiency for the downstream heat generators because the refrigerant temperature increases more on the downstream side. In addition, when multiple electronic components which serve as heat generators are mounted on the same circuit board, the distance from the heat receiving header to the heat radiating header mounted in correspondence with each heat generator varies, respectively.

The cooling device shown in FIGS. 2, 6 and 7 of U.S. Pat. No. 5,646,824 is configured in such a manner that a refrigerant reciprocates in a predetermined section. Thus, in order to apply this cooling device, a liquid transfer mechanism with a large discharge flow rate must be prepared to match the reciprocating flow rate to the heat receiving header with the longest path length. Furthermore, connecting all heat receiving headers in series causes a refrigerant recovered from the heat receiving header to pass over the heat radiating header in a portion where the distance from the heat receiving header to the heat radiating header is short. Consequently, it is necessary to form all the path lengths to fit to the longest portion. Furthermore, if the respective heat generation rates of multiple heat generators are different from one another, the heat radiating header may have the heat radiation capacity that can definitely release the heat of the refrigerant recovered from the heat receiving header mounted on the heat generator with the greatest heat generation rate.

In a notebook portable computer, the inner space of the housing has been already crowded with various components. Therefore, it should be avoided to increase the size of the cooling device more than necessary, such as making the liquid transfer mechanism be of a large capacity in accordance with the specific heat generator, configuring all the path lengths to fit to the longest one, or providing a heat radiating header with high heat radiation capacity to meet an electronic component with a large heat generating rate.

### SUMMARY

A cooling device according to one embodiment of the invention has a base substance formed in a plate form and having in its inside a channel through which a refrigerant circulates, and a flow mechanism to generate a stream of the refrigerant along the channel. A first heat receiving part, a second heat receiving part and a heat radiating part are provided on the base substance. The first heat receiving part has inside a first heat receiving section which is one section of the channel thermally connected to the first heat generator. The second heat receiving part has inside a second heat receiving section which is one section of the channel thermally connected to the second heat generator. The heat radiating part has inside a heat radiating section which is one section of the channel located downstream of the first heat receiving section and the second heat receiving section.

The cooling device prevents heat transferring between heat receiving parts which correspond to multiple heat generators.

An electronic apparatus according to one embodiment of the invention is provided with a housing, a circuit board which is built in the housing, a first heat generator and a second heat generator which are mounted on the circuit board and generate heat during operation, and the above-mentioned cooling device. In this electronic apparatus, multiple heat generators mounted on one circuit board are individually cooled by one cooling device without affecting one another.

For the purpose of summarizing the invention, certain aspects, advantages, and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic apparatus according to a first embodiment of the invention partially broken away;

FIG. 2 is an exemplary exploded perspective view showing the cooling device shown in FIG. 1 with a part of a circuit board which corresponds thereto;

FIG. 3 is an exemplary cross-sectional view of the cooling device on line A-A of FIG. 1;

FIG. 4 is an exemplary cross-sectional view of a cooling device according to a second embodiment of the invention on line corresponding to the line A-A of FIG. 1;

FIG. 5 is an exemplary cross-sectional view of a cooling device according to a third embodiment of the invention on line corresponding to the line A-A of FIG. 1;

FIG. 6 is an exemplary perspective view showing a cooling device arranged on a circuit board according to a fourth embodiment of the invention;

FIG. 7 is an exemplary exploded perspective view of the cooling device shown in FIG. 6;

FIG. 8 is an exemplary perspective view of a cooling device arranged on a circuit board according to a fifth embodiment of the invention;

FIG. 9 is an exemplary perspective view of a cooling device arranged on a circuit board according to a sixth embodiment of the invention;

FIG. 10 is an exemplary perspective view of a cooling device arranged on a circuit board according to a seventh embodiment of the invention;

FIG. 11 is an exemplary exploded perspective view of a cooling device according to an eighth embodiment of the invention with a part of a circuit board which corresponds thereto;

FIG. 12 is an exemplary plan view of a cooling device according to a ninth embodiment of the invention partially broken away; and

FIG. 13 is an exemplary plan view of a cooling device according to a tenth embodiment of the invention with a circuit board which corresponds thereto.

### DETAILED DESCRIPTION

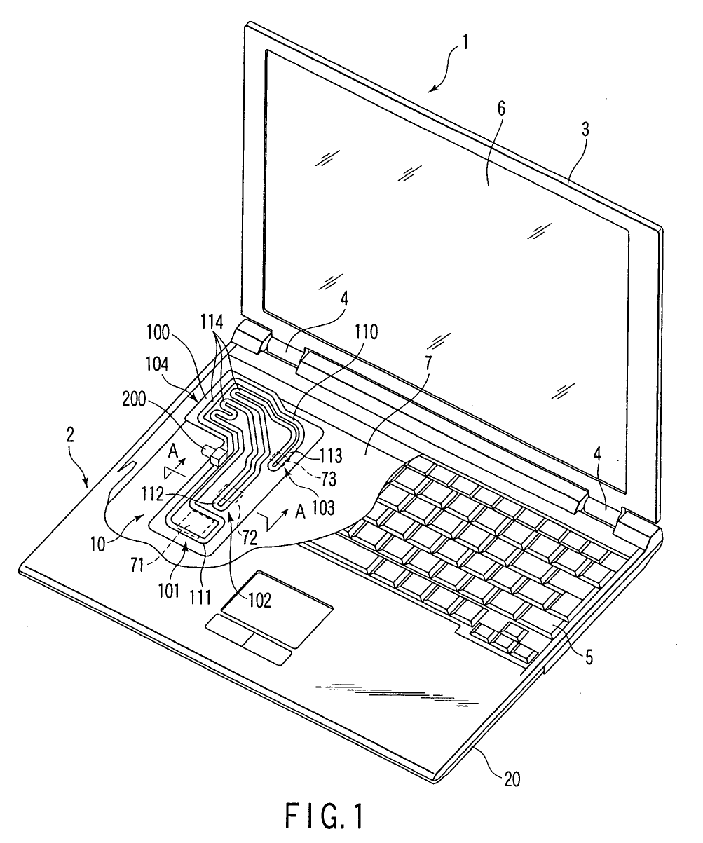

An electronic apparatus 1 with a cooling device 10 according to a first embodiment of the invention will be described referring to FIGS. 1 to 3. The electronic apparatus 1 shown in FIG. 1 has a main body 2 and a display unit 3, and is a notebook portable computer with these components coupled by a hinge 4. A keyboard 5 serving as an input means is arranged on the top surface of a housing 20 that configures the main body 2. The display unit 3 has a liquid crystal display 6 which is one example of a display device. A flat-panel display device such as organic electroluminescence display as the display device, in stead of the liquid crystal display 6,

This electronic apparatus 1 has a circuit board 7 and the cooling device 10 inside the housing 20. In the present embodiment, the circuit board 7 is provided with three heat generators: a first heat generator 71; a second heat generator 72; and a third heat generator 73. The first heat generator 71, the second heat generator 72, and the third heat generator 73 are electronic components represented by semiconductor elements, capacitors and the like which all generate heat during operation.

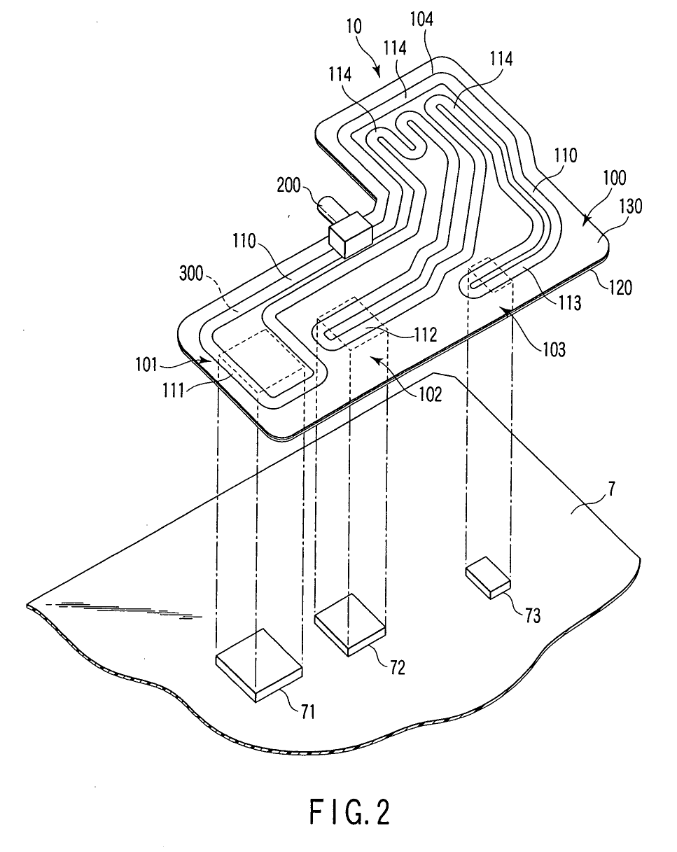

The cooling device 10 is provided with a base substance 100 and a pump 200. The base substance 100 is formed in a plate form along the circuit board 7 and has in its inside a channel 110 through which a refrigerant 300 circulates. The channel 110 is a so-called “closed loop” which makes a tour en suite without crossing inside the base substance 100 as shown in FIG. 2. On the base substance 100, a first heat receiving section 101, a second heat receiving section 102, a third heat receiving section 103 and a heat radiating section 104 are further provided.

The first heat receiving part 101 is disposed at the position that covers the first heat generator 71 and is thermally connected to the first heat generator 71 by a thermal conducting paste 8. The first heat receiving part 101 has a first heat receiving section 111 which is one section of the channel 110. The first heat receiving section 111 is disposed at the position that corresponds to the outer circumference of the first heat generator 71. Because the first heat receiving section 111 is arranged in this way, the heat is prevented from transferring to adjacent other heat receiving parts via the base substance 100, even if the calorific value of the first heat generator 71 is large.

The second heat receiving part 102 is disposed at the position that covers the second heat generator 72 and is thermally connected to the second heat generator 72 by the heat conducting paste 8. The second heat receiving part 102 has a second heat receiving section 112 which is one section of the channel 110. The second heat receiving section 112 lays on the area in which the second heat generator 72 and the second heat receiving part 102 are thermally connected.

The third heat receiving part 103 is disposed at the position that covers the third heat generator 73 and is thermally connected to the third heat generator 73 by the heat conducting paste 8. The third heat receiving part 103 has a third heat receiving section 113 which is one section of the channel 110. The third heat receiving section 113 lays on the area in which the third heat generator 73 and the third heat receiving part 103 are thermally connected.

The heat radiating part 104 is arranged at the position downstream of the first heat receiving section 111, the second heat receiving section 112, and the third heat receiving section 113, and has a heat radiating section 114 which is one section of the channel 110. The heat radiating section 114 of the heat radiating part 104 located downstream of each heat receiving part has a capacity to discharge the heat quantity greater than that received at the upstream heat receiving part while the heat radiating section 114 passes the refrigerant 300 to the further downstream heat receiving part.

In this embodiment, the heat radiating section 114 is disposed between the first heat receiving section 111 and the second heat receiving section 112, between the second heat receiving section 112 and the third heat receiving section 113, and the third heat receiving section 113 and the first heat receiving section 111, respectively. In addition, the heat radiating section 114 is disposed in a lump at one place. Each heat radiating section 114 has a sufficient length enough to discharge the heat quantity received at the heat receiving section disposed upstream. When the heat quantity received in the heat receiving section disposed upstream is large, the path length is secured by making the channel 110 of the heat radiating section 114, which is disposed downstream, meander.

The pump 200 is connected to an inflow port 105 and a discharge port 106 open to the base substance 100 in an interval from the heat radiating section 114 to the first heat receiving section 111. Because this pump 200 is one of the modes of the flow mechanism which generates a stream of refrigerant 300 and circulates the refrigerant 300 along the channel 110, it may be arranged at any place other than the first heat receiving part 101, the second heat receiving part 102, the third heat receiving part 103, and the heat radiating part 104. The type of the pump 200 may be an axial flow pump or diaphragm type pump as large as they are confined to this size.

The base substance 100 is configured by bonding two sheets of a heat-input side plate 120 and a heat-radiating side plate 130 together in the sheet thickness direction. The heat-input side plate 120 and the heat-radiating side plate 130 are formed by material with excellent heat conductivity such as copper, copper alloy and the like.

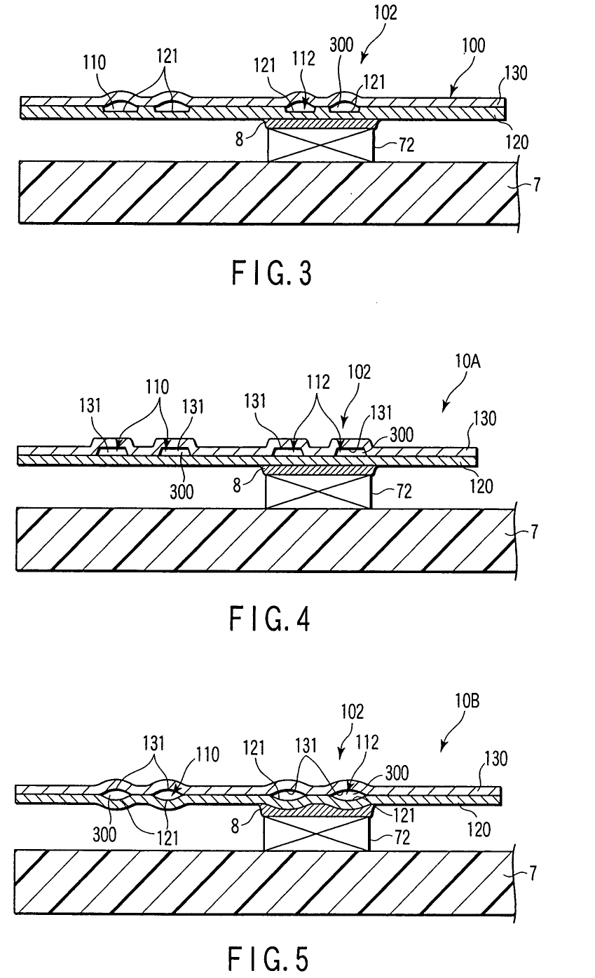

The heat-input side plate 120 disposed against the circuit board 7 has grooves 121 on the surface which is fit together with the heat-radiating-side plate 130 as shown in FIG. 3. This groove 121 is formed by etching. The groove 121 may be made by manufacturing methods such as embossing by a press, cutting by an endmill and the like in stead of forming by etching.

The heat-radiating-side plate 130 has uniform sheet thickness and is fit together with the heat-input-side plate 120 so as to cover the groove 121. The heat-input-side plate 120 and the heat radiating side plate 130 may be bonded by brazing, or attached together by bonding methods such as diffusion bonding, surface activated room-temperature bonding and the like. The channel 110 is formed inside the base substance 100 by covering the groove 121 by the heat-radiating-side plate 130.

The channel 110 is filled with demineralized water which serves as the refrigerant 300. It is acceptable that the refrigerant 300 is a fluid difficult to be degraded while it circulates in the channel 110 and at the same time a fluid which hardly corrodes, erodes or deteriorates the heat-input-side plate 120 and the heat-radiating-side plate 130, such as antifreeze liquid, oil, inert gas and the like. By the refrigerant 300 being filled, the heat-radiating-side plate 130 of the area that corresponds to the groove 121 is swollen in the direction away from the heat-input-side plate 120 as shown in FIG. 3. The position corresponding to the groove 121 may be bulged in advance by press forming, in stead of the bulging the heat-radiating-side plate 130 by the pressure for filling the refrigerant 300.

The cooling device 10 configured as above circulates the refrigerant 300 inside the channel 110 by the pump 200. In this case, the refrigerant 300 which has passed the first heat-receiving section 111, the refrigerant 300 which has passed the second heat-receiving section 112, and the refrigerant 300 which has passed the third heat-receiving section 113 are sure to go through the heat-radiating section 114 all on the downstream side before they go to the next heat-receiving section.

Consequently, the heat generated at the first heat generator 71 and recovered by the first heat receiving part 101 is radiated at the heat radiating part 104 and is never carried over to the second heat receiving part 102 located on the downstream side. In the same manner, the heat recovered by the second heat receiving part 102 is not carried over to the third heat receiving part 103, either or the heat recovered by the third heat receiving part 103 is not carried over to the first heat receiving part 101.

The channel 110 has the heat-radiating section 114 in the interval between the first heat-receiving section 111 and the second heat-receiving section 112, in the interval between the second heat-receiving section 112 and the third heat-receiving section 113, and in the interval between the third heat-receiving section 113 and the first heat-receiving section 111, respectively, even if the direction in which the pump 200 circulates the refrigerant 300 is changed. Therefore, the heat recovered at the upstream heat receiving part may not be carried over to the downstream heat receiving part.

In this way, the cooling device 10 which cools multiple heat generators of the first heat generator 71, the second heat generator 72, and the third heat generator 73 has the heat-radiating part 104 arranged among the first heat receiving part 101, the second heat receiving part 102, and the third heat receiving part 103, which are heat receiving parts provided correspondingly on individual heat generators. Therefore, the cooling device 10 individually cools the heat generators disposed on a plurality, because the cooling device 10 has the channel 110 formed en suite but suppresses heat from moving between heat receiving parts.

In addition, the cooling device 10 is not always required to match the distance from individual heat receiving parts to heat radiating parts in order to circulate the refrigerant 300. Furthermore, It may not be required a mechanism to adjust the flow rate of the refrigerant 300 flowing in each heat receiving part or a pump with large capacity to feed the refrigerant in parallel towards each heat receiving part, because the channel 110 is one continuous channel.

Cooling devices according to the second to tenth embodiments now will be described. The cooling devices of the second to tenth embodiments are explained with portions different from the first embodiment illustrated, and for the same portions, the description will be omitted. In addition, in each of the figures referred to, the components which have same functions as that of the cooling device according to the first embodiment will respectively applying the same reference symbols and may omit the description from followings.

A cooling device 10A according to the second embodiment of the invention will be discussed referring to FIG. 4. FIG. 4 is a figure in which the base substance 100 of the cooling device 10A of the second embodiment is cut away at the position corresponding to line A-A shown in FIG. 3 of the first embodiment.

In the cooling device 10A of the second embodiment, the shape of the heat-input-side plate 120 and the heat-radiating-side plate 130, which compose the substrate 100, differ from that of the first embodiment and the other components are the same as the first embodiment, when compared with the cooling device 10 of the embodiment of FIG. 1. The heat-input-side plate 120 in this embodiment has a flat shape along the circuit board 7. The heat-radiating-side plate 130 has a groove 131 that bulges out in the direction away from the heat-input-side plate 120 at the position corresponding to the channel 110 by press forming.

The heat-input-side plate 120 and the heat-radiating-side plate 130 are bonded together by room-temperature bonding or interface bonding, etc. As a result, the channel 110 is formed inside the substrate 100. The external surface of the heat-input-side plate 120 is flat as in the base substance 100 of the cooling device 10 according to the first embodiment. Consequently, in the first heat receiving part 101, the second heat receiving part 102, and the third heat receiving part 103, good thermal connectivity is achieved with the individually corresponding first heat generator 71, the second heat generator 72, and the third heat generator 73.

A cooling device 10B according to the third embodiment of the invention now will be described referring to FIG. 5. FIG. 5 is a figure in which the base substance 100 of the cooling device 10B of the third embodiment is cut away at the position corresponding to line A-A shown in FIG. 3 of the first embodiment.

In the cooling device 10B of the third embodiment, the shape of the heat-input-side plate 120 and the heat-radiating-side plate 130, which compose the substrate 100, are differ from that of the first embodiment and the other components are the same as the first embodiment, when compared with the cooling device 10 of the embodiment of FIG. 1. The heat-input-side plate 120 and the heat-radiating-side plate 130 in this embodiment have grooves 121, 131 in the form in which the portion corresponding to the channel 110 bulges out in the direction away from each other.

These grooves 121, 131 may not be press-forming in advance but may be bulged out as a result of filling the refrigerant 300. That is, when the heat-input-side plate 120 is put together with the heat-radiating-side plate 130, the external circumference that surrounds the channel 110 is bonded and then the refrigerant 300 is injected to the channel 110.

The cooling device 10B configured as above is difficult to generate warpage to the base substance 100 by thermal stress because the heat-input-side plate 120 and the heat-radiating-side plate 130 are formed into a mirror image with the bonded surface as a boundary.

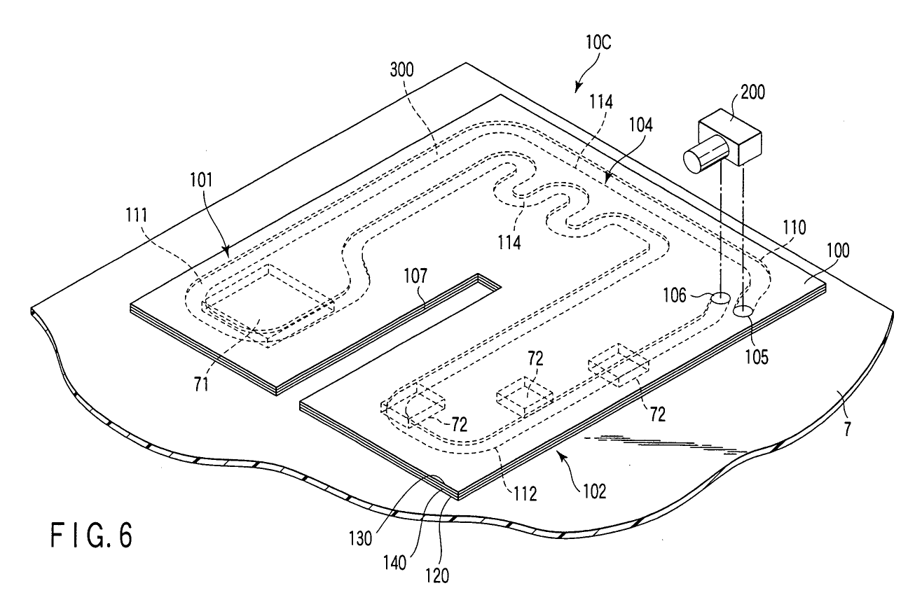

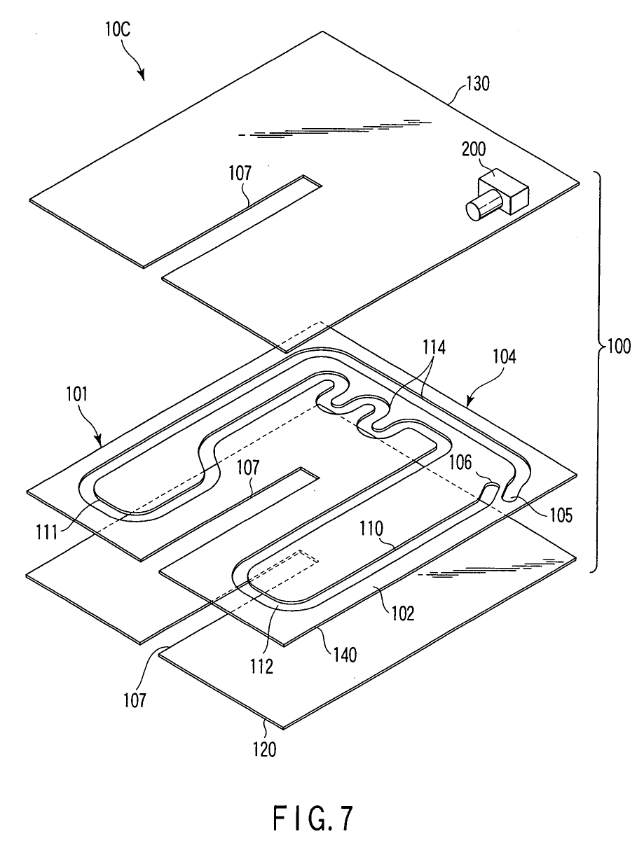

A cooling device 10C according to the fourth embodiment of the invention now will be described referring to FIGS. 6 and 7. The cooling device 10C of the fourth embodiment shown in FIG. 6 is provided with the first heat receiving part 101, the second heat receiving part 102, the heat-radiating part 104 and the pump 200. One first heat generator 71 and three second generators 72 are mounted on the circuit board 7. The first heat receiving part 101 is thermally connected to one first heat generator 71. The second heat receiving part 102 is disposed at the position to cover the three second heat generators 72 and thermally connected to these.

In addition, as shown in FIG. 6, a slit 107 is provided between the first heat receiving part 101 and the second heat receiving part 102. In this manner, linear thermal conduction between the first heat receiving part 101 and the second heat receiving part 102 is suppressed. The second heat receiving section 112 which is the channel 110 disposed to the second heat receiving part 102 is disposed to pass the vicinity of each of the three second heat generators 72. The heat radiating section 114 located at the downstream of the second heat receiving section 112 has a capacity sufficient to discharge the calories which the three second heat generators 72 generate.

This base substance 100 has an intermediate member 140 inserted between the heat-input-side plate 120 and the heat-radiating-side plate 130 as shown in FIG. 7. The intermediate member 140 has the portion which becomes the channel 110 bored. By fitting together the heat-input-side plate 120, the intermediate member 140, and the heat-radiating-side plate 130 in three-ply, a closed channel 110 is formed.

Because in the cooling device 10C, the heat-input-side plate 120, the heat-radiating-side plate 130 and the intermediate member 140 are of a flat shape free of any irregularities, it is manufactured easily by punching by press machine. In addition, by changing the sheet thickness size of the intermediate member 140, the amount of the circulated refrigerant 300 can be optionally set.

That is, the cooling device 10C can be manufactured by flexibly changing the flow rate of the refrigerant 300, width size of the channel 110, layout of the channel 110 and other specifications in accordance with the required cooling capacity. Furthermore, since the outer surface of the heat-input-side plate 120 is flat, good adhesion can be achieved between the first heat receiving part 101 to the first heat generator 71 and the second heat receiving part 102 to the second heat generator 72.

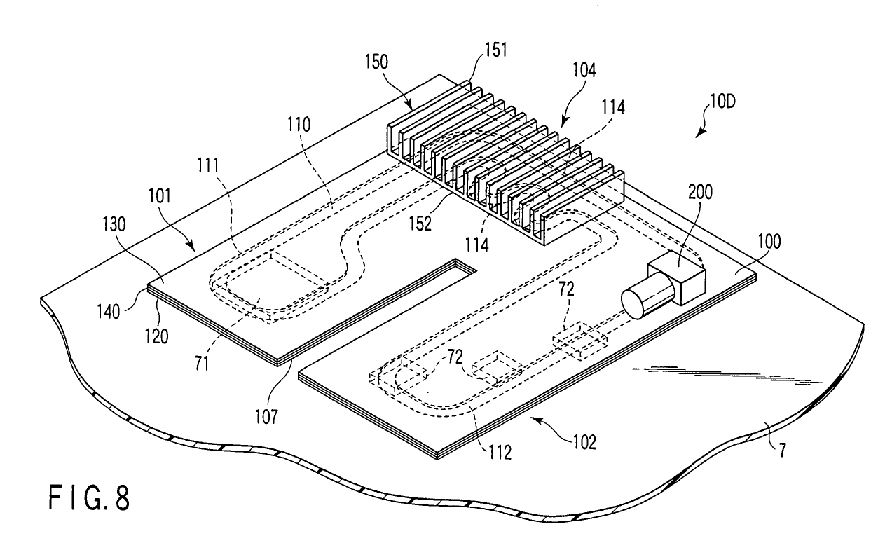

A cooling device 10D according to the fifth embodiment of the invention will be described referring to FIG. 8. The cooling device 10D shown in FIG. 8 is provided with a heat-radiating member 150 on the heat-radiating part 104. The heat-radiating member 150 is a so-called heat sink which has a large number of fins 151 that stand up from a base plate 152. The heat-radiating member 150 is formed in a size that covers the area in which the heat-radiating section 114 is disposed and is thermally connected to the heat-radiating-side plate 130 by brazing or interface bonding, etc. The cooling device 10D positively discharges heat from the channel 110 by equipping the heat radiating member 150. Consequently, as compared to a cooling device of the same size, this cooling device 10D can be applied to a heat generator with a large heat-radiation rate.

The heat-radiating member 150 and the heat-radiating-side plate 130 may be bonded together by applying a heat-conductive paste between them. In addition, the heat-radiating member 150 may have a large number of pins formed in stead of the fins 151. Other configurations are the same as those of the cooling device 10C of the fourth embodiment.

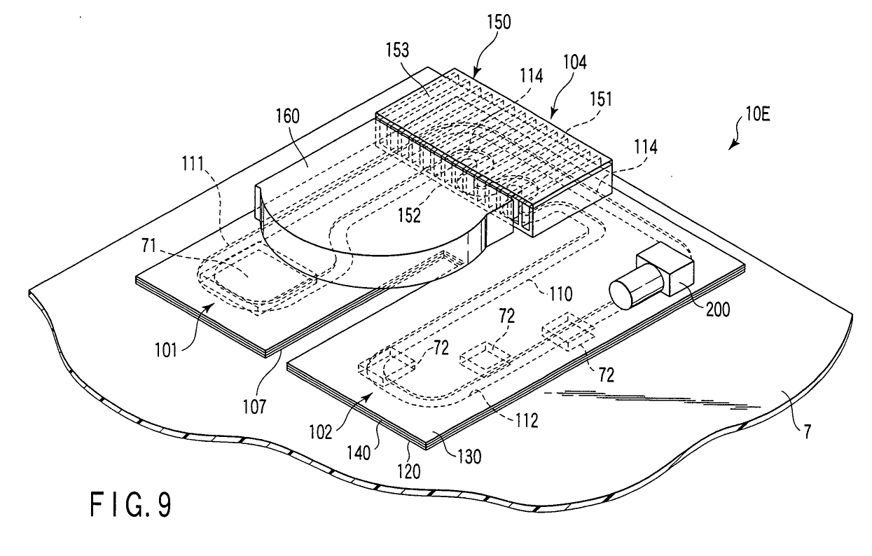

A cooling device 10E according to the sixth embodiment of the invention will be described referring to FIG. 9. The cooling device 10E show in FIG. 9 is further provided with a fan 160 in the cooling device 10D of the fifth embodiment. The fan 160 blows air along the direction in which the fins 151 mounted on the heat-radiating member 150 extend in parallel. Since the air around the heat-radiating member 150 is forcibly ventilated, the heat transfer efficiency of the heat-radiating member 150 to the air is improved. In addition, the heat-radiating member 150 has a cover 153 which closes the tip of fins 151 in parallel to the base plate 152. In this manner, air completely reaches throughout the full length of fins 151 and the heat radiation rate is improved, too. Other configurations are the same as those of the cooling device 10D of the fifth embodiment.

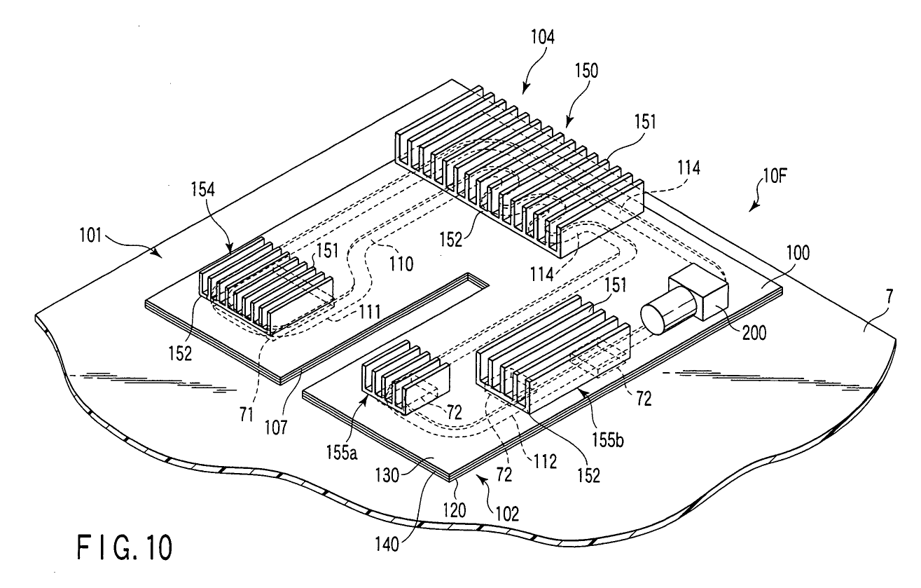

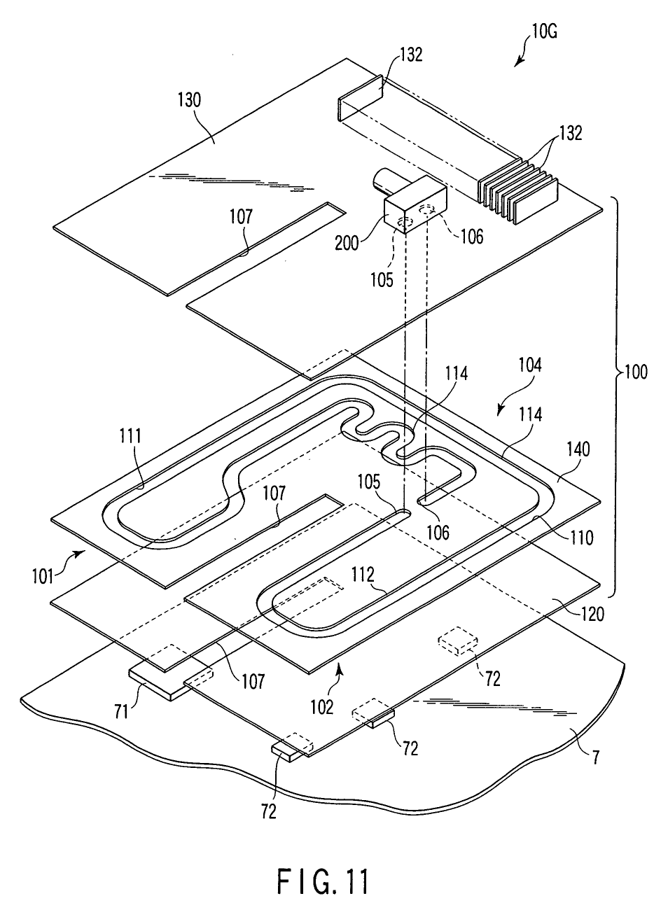

A cooling device 10F according to the seventh embodiment of the invention will be described referring to FIG. 10. The cooling device 10F shown in FIG. 10 is further provided with heat radiating members 154, 155a, 155b mounted on the first heat receiving part 101 and the second heat receiving part 102, respectively, as compared to the cooling device 10D of the fifth embodiment. The heat radiating member 154 is mounted on the outer surface of the first heat receiving part 101 on the side opposite to the surface which is thermally connected to the first heat generator 71. The heat-radiating member 155a is disposed to the outer surface on the side opposite to the portion in which one of the three second heat generators 72 is thermally connected to the second heat receiving part 102, and the heat-radiating member 155b is disposed to the outer surface on the side opposite to the portion in which the remaining two second heat generators 72 are thermally connected to the second heat receiving part 102. Other configurations are the same as those of the cooling device 10D in the fifth embodiment.

In this way, the cooling device 10F is provided with the heat-radiating members 154, 155a, 155b on the outer surfaces of the heat receiving units corresponding to the heat generators. Therefore, the heat-radiating member 150 provided on the heat-radiating part 104 is decreased in size. In addition, since the flow rate of the refrigerant 300 which is circulated in the channel 110 may be reduced, the pump 200 may be replaced with a small-capacity pump with a small discharge volume.

A cooling device 10G according to the eighth embodiment of the invention will be described referring to FIG. 11. The cooling device 10G shown in FIG. 11 has a heat-radiating fin 132 which serves as the heat-radiating member formed integrally with the heat-radiating-side plate 130 of the base substance 100. Because the heat-radiating fin 132 is directly formed on the base substance 100, the heat radiation efficiency of the heat-radiating part 104 is improved. Though the arrangement of the pump 200 differs from that of the cooling device 10D in the fifth embodiment, it is the same as the cooling devices in other embodiments in terms of being disposed in the channel 110. Other components are the same as those of the cooling device 10D of the fifth embodiment.

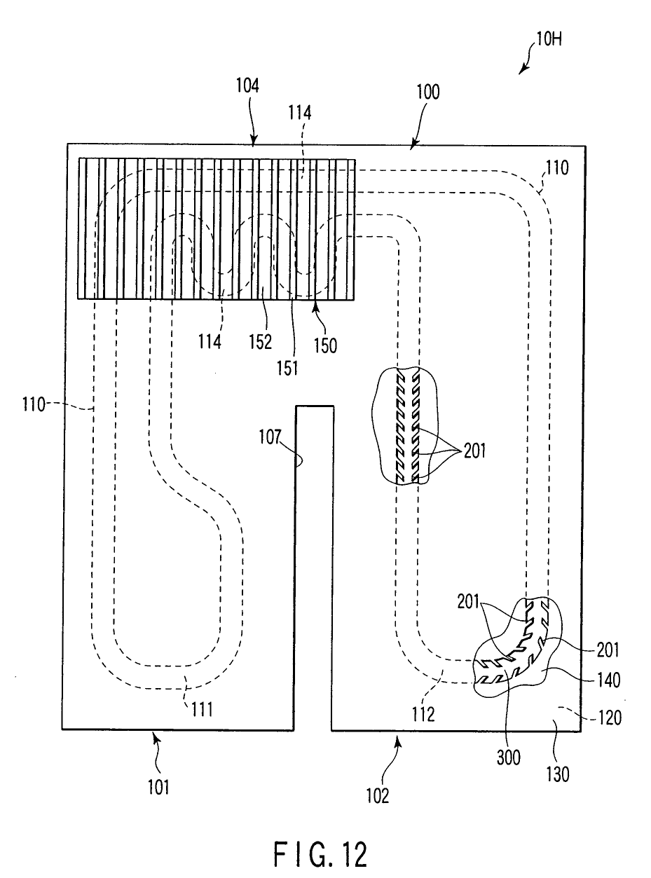

A cooling device 10H according to the ninth embodiment of the invention will be described referring to FIG. 12. When the cooling device 10H shown in FIG. 12 is compared to the cooling device 10D of the fifth embodiment, it has no pump 200 which is the flow mechanism to generate a stream of the refrigerant 300 along the channel 110. In place of it, protrusions 201 are provided on the inner wall of the channel 110, as the flow mechanism. The protrusions 201 are formed in the state inclined toward the direction in which the refrigerant 300 is desired to be circulated as shown in FIG. 12. In FIG. 12, the protrusions 201 are only partially illustrated, but are provided throughout the whole circumference of the channel 110. Other components are the same as those of the cooling device 10D of the fifth embodiment.

The protrusions 201 induce self-excited vibrations with the refrigerant 300 when vibrations are applied to the base substance 100 from the external and circulate the refrigerant 300 along the channel 110. The detailed shape and the angle inclined to the downstream side of the protrusions 201 may be arbitrarily determined in accordance with the viscosity, density, temperature, and pressure of the refrigerant 300 that flows in the channel 110 as well as the shape of the channel 110, and the frequency band of the vibrations applied from the externally.

In the cooling device 10H configured in this way, the channel 110 provided on the base substance 100 to which the heat-input-side plate 120, the intermediate member 140 and the heat-radiation-side plate 130 are put together is in the completely closed state to the outside and there is no jointed portion with a pump, etc., the cooling device 10H is completely free of leakage of the refrigerant. That is, the cooling device 10H provides superb durability with time.

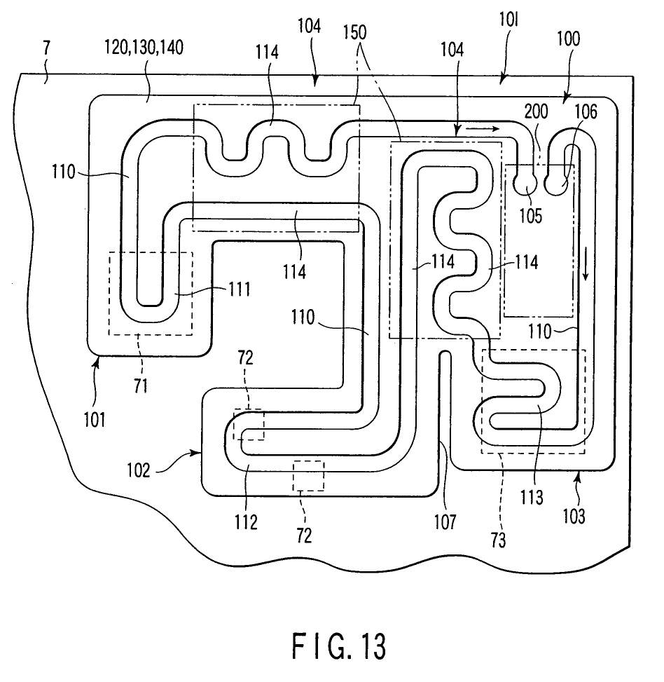

A cooling device 10I according to the tenth embodiment of the invention will be described referring to FIG. 13. In the cooling device 10I shown in FIG. 13, the base substance 100 has the first heat receiving part 101, the second heat receiving part 102 and the third heat receiving part 103. One first heat generator 71, two second heat generators 72 and one third heat generator 73 are mounted on the circuit board 7. The first heat receiving part 101 is thermally connected to the first heat generator 71, the second heat receiving part 102 is thermally connected to the two second heat generators 72, and the third heat receiving part 103 is thermally connected to the one third heat generator 73.

The first heat receiving part 101 and the second heat receiving part 102 are arranged on the end portion which extends so as to surround the fan 160, etc. Thus, direct heat conduction between the first heat receiving part 101 and the second heat receiving part 102 is cut off. Between the second heat receiving part 102 and the third heat receiving part 103, a slit 107 is provided to cut off the heat conduction in this interval. The third heat receiving part 103 is thermally connected to the third heat generator 73 having a greater heat generation rate than that of the first heat generator 71. The third heat receiving section 113 disposed to the third heat receiving part 103 meanders in the area which corresponds to the portion in which the third heat generator 73 and the third heat receiving part 103 are thermally connected. By meandering the heat receiving section, greater heat can be received from the corresponding heat generator and the cooling efficiency is improved.

In addition, to this base substance 100, a heat radiating part is divided and provided in two places. In a first heat radiating part 104A, the heat radiation section 114 provided downstream of the first heat receiving section 111 of the first heat receiving part 101 and the heat radiating section 114 provided downstream of the second heat receiving section 112 of the second heat receiving part 102 are disposed. In a second heat radiating part 104B, the heat radiating section 114 provided downstream of the third heat receiving section 113 of the third heat receiving part 103 is disposed. The heat-radiation member 150 is mounted on each of the first heat radiating part 104A and the second heat radiating part 104B, respectively.

The cooling device 10I provided as above has the first heat receiving part 101, the second heat receiving part 102 and the third heat receiving part 103 separated from one another, and has the heat radiating sections 114 downstream of the first heat receiving section 111, downstream of the second heat receiving section 112 and downstream of the third heat receiving section 113, respectively. Therefore the first heat generator 71, the second heat generator 72 and the third heat generator 73 can be efficiently cooled without affecting one another by the heat generated from other heat generating parts. Furthermore, by dividing and disposing the heat radiating part into the first heat radiating part 104A and the second heat generating part 104B, diversity can be achieved for the layout of each part in the base substance 100.

In the cooling devices 10, 10A, 10B, 10C, 10E, 10F, 10G, 10H, and 10I from the first to tenth embodiments as described above, the detailed portions which differ from one another may be arbitrarily replaced mutually with part of other embodiments.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

What is claimed is:

1. A cooling device comprising:
a base substance formed in a plate form and having in its inside a channel through which a refrigerant circulates, said substance is provided with:
a first heat receiving part which is thermally connected to at least one of a first heat generator and has in its inside a first heat receiving section that is one section of the channel,
a second heat receiving part which is thermally connected to at least one of a second heat generators and has in its inside a second heat receiving section that is one section of the channel, and
a heat radiating part which has in its inside heat radiating sections that are located downstream of the first heat receiving section and the second heat receiving section and is one section of the channel; and
a flow mechanism which generates a stream of the refrigerant along the channel.

2. The cooling device according to claim 1, wherein
the base substance forms the channel by bonding two plates together in the sheet thickness direction.

3. The cooling device according to claim 1, wherein
the base substance is configured by bonding together an intermediate member in which the channel is formed and two plates that sandwiches said intermediate member therebetween in the sheet thickness direction.

4. The cooling device according to claim 1, wherein
the first heat receiving part and the second heat receiving part are suppressed thermal conduction therebetween.

5. The cooling device according to claim 1, wherein
the first heat receiving section or the second heat receiving section meanders.

6. The cooling device according to claim 1, wherein
the first heat receiving section is arranged at a position corresponding to an outer circumference of the first heat generator.

7. The cooling device according to claim 1, wherein
the second heat receiving section is arranged at a position corresponding to an outer circumference of the second heat generator.

8. The cooling device according to claim 1, wherein
the heat radiating part has a heat radiating member.

9. The cooling device according to claim 8, wherein
the heat radiating member is formed integrally with the heat radiating part.

10. The cooling device according to claim 8, wherein
the heat radiating member is formed separately from the heat radiating part and is thermally connected to the heat radiating part.

11. The cooling device according to claim 8, wherein
the heat radiating part is provided with a fan which forcibly ventilates air around the heat radiating member.

12. The cooling device according to claim 1, wherein
the flow mechanism is a pump which circulates the refrigerant along the channel.

13. The cooling device according to claim 1, wherein
the flow mechanism is protrusions which are formed on the inner surface of the channel and generate the stream of the refrigerant by vibrations added to the base substance.

14. The cooling device according to claim 1, further comprising:
a heat radiating member which is provided on the outer surface of the first heat receiving part on the side opposite to the surface thermally connected to the first heat generator.

15. The cooling device according to claim 1, further comprising:
a heat radiating member which is provided on the outer surface of the second heat receiving part on the side opposite to the surface thermally connected to the second heat generator.

16. An electronic apparatus comprising:
a housing;
a circuit board provided in the housing;
a first heat generator and a second heat generator which are mounted to the circuit board and generate heat during operation; and
a cooling device, said cooling device including:
a base substance formed in a plate form and having in its inside a channel through which a refrigerant circulates, said base substance is provided with:
a first heat receiving part which is thermally connected to at least one of a first heat generator and has in its inside a first heat receiving section that is one section of the channel;
a second heat receiving part which is thermally connected to at lease one of a second heat generator and has in its inside a second heat receiving section that is one section of the channel; and
a heat radiating part which has a heat radiating section that is located downstream of the first heat receiving section and the second heat receiving section and is one section of the channel; and
a flow mechanism that generates a stream of the refrigerant along the channel.
